(19) United States
(12) Patent Application Publication
(10) Pub. No.: US 2025/0159849 A1
(43) Pub. Date: May 15, 2025

(54) POWER MODULE TEMPERATURE MANAGEMENT DEVICE

(71) Applicants: Hyundai Motor Company, Seoul (KR); Kia Corporation, Seoul (KR)

(72) Inventor: Tae Hwa KIM, Hwaseong-Si (KR)

(73) Assignees: Hyundai Motor Company, Seoul (KR); Kia Corporation, Seoul (KR)

(21) Appl. No.: 18/389,479

(22) Filed: Nov. 14, 2023

(30) Foreign Application Priority Data
Jun. 19, 2023 (KR) 10-2023-0078083

(51) Int. Cl. H05K 7/20

(52) U.S. Cl. CPC H05K 7/20927; H05K 7/20945

(57) ABSTRACT

Introduced is a power module temperature management device including a flow path including a first section thermally connected to the power module and a second section connected in series to the first section for a coolant to flow from the second section to the first section, and a coolant cooler thermally connected to the second section of the flow path and cooling the coolant flowing into the second section according to a predetermined condition.

### CROSS REFERENCE TO RELATED APPLICATION

The present application claims priority to Korean Patent Application No. 10-2023-0078083, filed Jun. 19, 2023, the entire contents of which is incorporated herein for all purposes by this reference.

### BACKGROUND OF THE PRESENT DISCLOSURE

### Field of the Present Disclosure

The present disclosure relates to a power module temperature management device which is capable of enhancing the power density of the power module by effectively managing the temperature of coolant.

### Description of Related Art

With the growing interest in the environment, there is a trend of increasing eco-friendly vehicles provided with electric motors as power sources. Eco-friendly vehicles, also known as electrified vehicles, include electric vehicles (EVs) and hybrid electric vehicles (HEVs).

In electrified vehicles, an inverter is typically provided to convert direct current power to alternating current power for motor operation, and the inverter is usually composed of one or multiple power modules incorporating semiconductor chips that perform switching functions.

Meanwhile, during operation, the semiconductor chip of the power module generates heat due to the high voltage and large current. The heat generated by the semiconductor chip can affect the operation of the power module, so it is necessary to dissipate the heat to ensure the stable operation of the power module.

Various methods are being employed to dissipate heat in power modules, and one example is connecting cooling channels to the substrate and improving cooling efficiency by circulating a coolant such as cooling water through those channels.

In such methods, where the temperature of the coolant significantly affects the cooling of the power module, there is a demand for solutions capable of properly control the coolant temperature.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a power module temperature management device which is configured for improving the operational performance and efficiency of the power module by appropriately controlling the temperature of the coolant before the coolant flows into the power module.

To accomplish the above object, a device for managing the temperature of a power module according to an exemplary embodiment of the present disclosure includes a flow path including a first section thermally connected to the power module and a second section connected in series to the first section for a coolant to flow from the second section to the first section, and a coolant cooler thermally connected to the second section of the flow path and cooling the coolant flowing into the second section according to a predetermined condition.

For example, the second section may be oriented in the opposite direction to the direction facing the first section for the coolant cooled through heat exchange with the outside of the first section after passing through the first section to flow into the second section.

For example, the coolant cooler may include a first cooling unit including a fluid tank filled with a fluid having a boiling point lower than a boiling point of the coolant and connected to an external side of the second section.

For example, the predetermined condition may be satisfied based on a temperature of the coolant flowing into the second section being equal to or greater than the boiling point of the fluid.

For example, the fluid tank may include a shape surrounding the external side of the second section and being penetrated by the second section for the fluid to contact with the external side of the second section.

For example, the coolant cooler may include a second cooling unit connected to the second section and operated by receiving energy from a power source, and a control unit electrically connected to the second cooling unit and configured for controlling the second cooling unit to cool the coolant according to the predetermined condition.

For example, the second cooling unit may include at least one of a fan and a Peltier device.

For example, the predetermined condition may be satisfied based on a power equal to or greater than a predetermined reference power being applied to the power module.

For example, the predetermined reference power may be set corresponding to a thermal resistance of the power module.

For example, the predetermined condition may be satisfied based on a temperature of the coolant flowing into the first section being equal to or greater than a predetermined reference temperature.

For example, the coolant cooler may include a first cooling unit including a fluid tank filled with a fluid having a boiling point lower than a boiling point of the coolant and connected to an external side of the second section, a second cooling unit connected to the second section and operated by receiving energy from a power source, and a control unit electrically connected to the second cooling unit and configured for controlling the second cooling unit to cool the coolant according to the predetermined condition.

For example, the predetermined condition may include a first condition and a second condition, the first cooling unit may cool the coolant flowing into the second section based on the first condition being satisfied, and the second cooling unit may cool the coolant flowing into the second section based on the second condition being satisfied.

For example, the second cooling unit may be connected to the external side of the first cooling unit.

For example, the flow path may include a plurality of channels connected in parallel and spaced from each other in the second section in a direction perpendicular to a flow direction of the coolant.

For example, the flow path may include a heat exchanger formed on at least one of internal and external portions of the second section to transfer heat of the coolant to the heat exchanger.

Through the various embodiments of the present disclosure as described above, it becomes possible to reliably manage the temperature of the semiconductor chips in the power module, effectively ensuring the operational performance and reliability of the power module.

Furthermore, by enhancing the performance of the power module through temperature adjustment of the coolant, without requiring any modifications to the structure or materials of the power module, it becomes possible to allow for an expanded design flexibility and cost savings for the power module.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a diagram illustrating a power module temperature management device according to an exemplary embodiment of the present disclosure;

FIG. 2 is a diagram illustrating a first cooling unit of a coolant cooler according to an exemplary embodiment of the present disclosure:

FIG. 3 is a diagram illustrating a second colling section of a coolant cooler according to an exemplary embodiment of the present disclosure:

FIG. 4 is a diagram illustrating a coolant cooler with both a first cooling unit and a second cooling unit together according to an exemplary embodiment of the present disclosure:

FIG. 5 is a diagram illustrating a configuration where a second section of a flow path is formed in a parallel manner according to an exemplary embodiment of the present disclosure; and

FIG. 6 is a diagram illustrating the configuration where a heat exchanger is applied to a second section of a flow path according to an exemplary embodiment of the present disclosure.

It may be understood that the appended drawings are not necessarily to scale, presenting a somewhat simplified representation of various features illustrative of the basic principles of the present disclosure. The predetermined design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

The specific structural or functional descriptions of the exemplary embodiments of the present disclosure included in the present specification or patent application are illustrative examples intended to describe embodiments of the present disclosure, and the exemplary embodiments of the present disclosure may be implemented in various forms and should not be construed as being limited to those described in the present specification or the application.

The exemplary embodiments of the present disclosure may be subject to various modifications and can take on different forms, so specific embodiments are illustrated in the drawings and described in detail in the present specification or the application. However, the present should not be construed as limiting the exemplary embodiments of the present disclosure to specific included form, but rather should be understood to encompass all modifications, equivalents, or substitutes that fall within the scope of the concept and technological scope of the present disclosure.

Unless otherwise defined, all terms used herein, including technical or scientific terminology, have the same meaning as commonly understood by those skilled in the art to which the present disclosure belongs. It will be further understood that terms, including those defined in commonly used dictionaries, should be interpreted in a manner consistent with their meaning in the context of the relevant field and should not be interpreted in an idealized or overly formal sense unless explicitly defined in the present specification.

Hereinafter, descriptions are made of the exemplary embodiments disclosed in the present specification with reference to the accompanying drawings in which the same reference numbers are assigned to refer to the same or like components and redundant description thereof is omitted.

As used in the following description, the suffix “module” and “unit” are granted or used interchangeably in consideration of easiness of description but, by itself, including no distinct meaning or role.

Furthermore, detailed descriptions of well-known technologies related to the exemplary embodiments included in the present specification may be omitted to avoid obscuring the subject matter of the exemplary embodiments included in the present specification. Furthermore, the accompanying drawings are only for easy understanding of the exemplary embodiments included in the present specification and do not limit the technical spirit included herein, and it should be understood that the exemplary embodiments include all changes, equivalents, and substitutes within the spirit and scope of the present disclosure.

As used herein, terms including an ordinal number such as “first” and “second” may be used to describe various components without limiting the components. The terms are used only for distinguishing one component from another component.

It will be understood that when a component is referred to as being “connected to” or “coupled to” another component, it may be directly connected or coupled to the other component or intervening component may be present. In contrast, when a component is referred to as being “directly connected to” or “directly coupled to” another component, there are no intervening component present.

As used herein, the singular forms are intended to include the plural forms as well, unless the context clearly indicates otherwise.

It will be further understood that the terms “comprises” or “has,” when used in the present specification, specify the presence of a stated feature, number, step, operation, component, element, or a combination thereof, but they do not preclude the presence or addition of one or more other features, numbers, steps, operations, components, elements, or combinations thereof.

For example, each controller may include a communication device communicating with another controller or sensor to control a function in charge, a memory that stores operating system or logic instructions and input/output information, and one or more processors for determination, operation, and decision-making necessary for functions in charge.

According to an exemplary embodiment of the present disclosure, the power module temperature management device adjusts the coolant temperature before it flows into the power module, improving the cooling performance of the power module without requiring any structural modifications and enabling enhanced output performance.

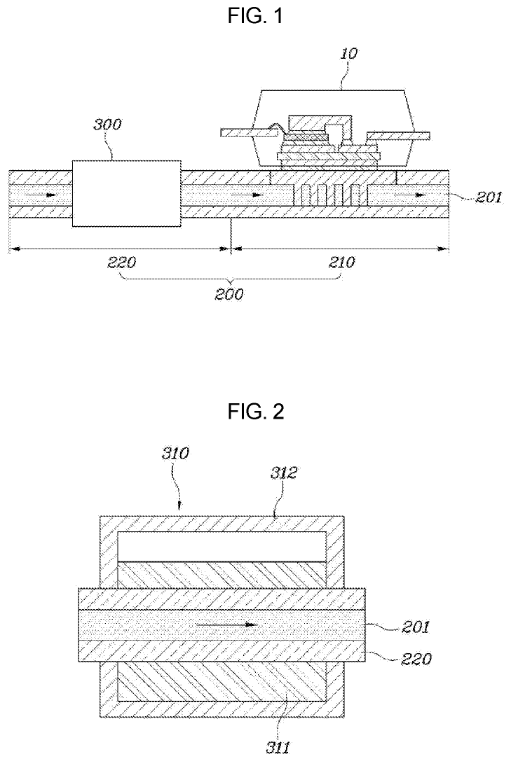

First, a description includes the overall configuration of the power module temperature management device according to an exemplary embodiment of the present disclosure with reference to FIG. 1.

FIG. 1 is a cross-sectional view exemplarily illustrating the power module temperature management device according to an exemplary embodiment the present disclosure.

With reference to FIG. 1, the power module temperature management device according to an exemplary embodiment of the present disclosure is connected to the power module 10 and includes a flow path 200 and a coolant cooler 300. However, it should be noted that FIG. 1 represents the components primarily related to the description of the power module temperature management device according to an exemplary embodiment of the present disclosure, and the actual power module temperature management device may include more or fewer components than shown.

Here, the power module 10 may include a substrate and a semiconductor chip mounted on the substrate.

The semiconductor chip may be turned on or off according to a switching signal, and the conduction between the upper and lower sides of the semiconductor chip is determined by the ON/OFF state.

The semiconductor chip may be implemented as a switching device such as an insulated gate bipolar transistor (IGBT) or a metal-oxide-semiconductor field-effect transistor (MOSFET), and the material may be silicon (Si) or silicon carbide (SiC).

During the operation of the power module, heat is generated due to the operating loss of the semiconductor chip, elevated temperature in the power module may adversely affect the performance and lifespan of the power module.

Therefore, it is necessary to manage the semiconductor chip to operate within the maximum operating temperature, which may be determined differently depending on the type of semiconductor chip, the structure of the power module 10, and the output performance of an inverter to which the power module 10 is applied.

Meanwhile, the substrate may include an insulating layer and a metal layer disposed on one or both sides of the insulating layer.

The insulating layers may be configured to electrically isolate the inside and the outside of the power module 10, and for example, it may be implemented in ceramic.

The metal layer on one side of the insulating layer facing the semiconductor chip may be intended for conduction within the power module 10 and patterned to establish electrical connections within the power module 10.

The metal layer on the other side of the insulating layer facing the outside of the power module 10 may be intended for cooling the power module by emitting heat from the inside of the power module 10 to the outside through heat exchange with the outside.

The metal layers may be implemented using copper (Cu), which has excellent electrical and thermal conductivity, and in the instant case, the substrate may be implemented using active metal brazed (AMB) or direct bonded copper (DBC) method.

Meanwhile, two substrates may also be disposed symmetrical to be spaced from each other with the semiconductor chip in the middle, and in the instant case, the present method may be referred to as double-sided cooling. On the other hand, when the power module 10 consists only of a semiconductor chip and a substrate on which the semiconductor chip is mounted, the present method may be referred to as single-sided cooling.

In the double-sided cooling method, the heat generated from the semiconductor chip may be emitted to the outside through the substrates on both sides of the semiconductor chip, i.e., the heat dissipation may be carried out in both directions, compared to the single-sided cooling method in which the heat dissipation may be carried out in one direction.

Because the power module temperature control device in an exemplary embodiment of the present disclosure improves the cooling and output performance of the power module 10 by adjusting the temperature of the coolant 201, it may be applied to the double-sided cooling method and the single-sided cooling method regardless of the configuration of the substrate(s).

Meanwhile, the power module 10 may be implemented in an indirect cooling method in which the substrate is connected to the flow path 200 through a thermal interface material (TIM) so that the heat of the substrate may be indirectly transferred to the coolant 201, or in a direct cooling method in which the substrate is inserted into the flow path 200 so that it is in direct contact with the coolant 201.

Similarly, because the power module temperature control device in an exemplary embodiment of the present disclosure improves the cooling and output performance of the power module 10 by adjusting the temperature of the coolant 201, it may be applied to both the direct and indirect cooling methods.

That is, the power module temperature control device in an exemplary embodiment of the present disclosure achieves cooling of the power module 10 by controlling the temperature of the coolant 201 that acts on the cooling of the power module 10, instead of improving the heat dissipation performance by changing the structure or material of the power module 10 itself. As a result, it is possible to improve the cooling performance of the power module 10 without encountering difficulties in design and development and incurring additional costs which may are caused by altering the structure or material of the power module 10.

Meanwhile, the flow path 200 includes a first section 210 thermally connected to the power module 10 and a second section 220 connected in series with the first section 210, and the coolant 201 may flow from the second section 220 to the first section 210.

The second section 220 is oriented in the opposite direction to the direction facing the first section 210 so that the coolant 201 cooled through heat exchange with the outside of the first section after passing through the first section 210 may be flowing into the second section 220.

That is, the coolant 201 may be circulated in the flow path 200, absorbing heat from around the power module 10 through heat exchange and then emitting the absorbed heat before returning the power module 10.

The coolant 201 may be, for example, water, and specific composition thereof may be appropriately determined based on factors such as the output performance of the power module 10 and the temperature required for stable operation of the power module.

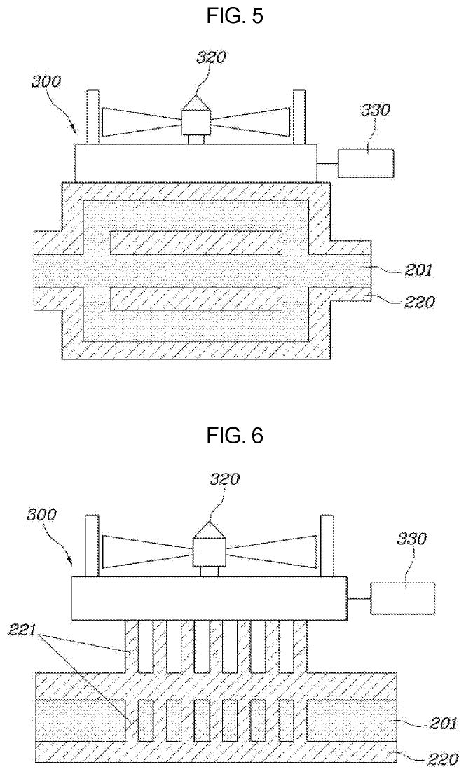

The shape or structure of the flow path 200 will be described later in detail with reference to FIG. 5 and FIG. 6.

In an exemplary embodiment of the present disclosure, the coolant cooler 300 is thermally connected to the second section 220 of the flow path 200 to cool the coolant 201 flowing into the second section 220 according to a predetermined condition.

The coolant cooler 300 may include a first cooling unit 310 which may maintain the temperature of the coolant 201 below a certain temperature, a second cooling unit 320 that receives energy from a power source and operates, and a control unit 330 which may adjust the temperature of the coolant 201 through the second cooling unit 320 when powerful cooling for the power module 10 is required. However, the configuration of the coolant cooler 300 is not necessarily limited thereto and may include more or fewer components in actual implementation.

By connecting the coolant cooler 300 to the second section 220 of the flow path 200, the temperature of the coolant 201 flowing from the second section 220 to the first section 210 may be adjusted before reaching the power module 10.

The coolant 201 has different temperatures in each section of the flow path 200, and because the temperature in the first section 210, particularly the temperature of the coolant 201 entering the first section 210, plays a substantial and important role in cooling the power module 10, the cooling of the power module 10 through the coolant 201 may be performed within a more consistent temperature range or, if necessary, may be performed more strongly with the coolant cooler 300.

Even when an additional device such as a radiator is connected to the flow path 200 for cooling the coolant 201, further improvement in the cooling performance of the power module 10 may be achieved by cooling the previously cooled coolant 201 once again just before the cooling operation of the power module 10.

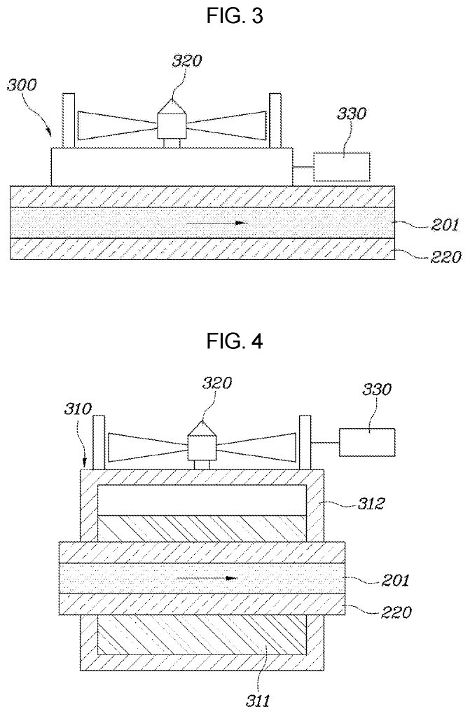

Hereinafter, the components forming the coolant cooler 300 according to an exemplary embodiment of the present disclosure are described in more detail with reference to FIG. 2, FIG. 3 and FIG. 4.

FIG. 2 is a diagram illustrating a first cooling unit of a coolant cooler according to an exemplary embodiment of the present disclosure.

With reference to FIG. 2, the first cooling unit 310 includes a fluid tank 312 filled with a fluid 311 having a boiling point lower than that of the coolant 201 and connected to the external side of the second section 220.

In the instant case, the predetermined condition for the cooling of the coolant 201 flowing into the second section 220 may be satisfied when the temperature of the coolant 201 flowing into the second section 220 is equal to or greater than the boiling point of the fluid 311.

For example, assuming that the boiling points of the coolant 201 and the fluid 311 are 100 degrees and 60 degrees, respectively, when the temperature of the coolant 201 becomes equal to or greater than 60 degrees during the cooling process of the power module 10, the fluid 311 that has absorbed the heat from the coolant 201 may vaporize. Here, the heat of the coolant 201 is absorbed for the vaporization of the fluid 311, leading to a decrease in the temperature of the coolant 201.

In detail, when the first cooling unit 310 according to an exemplary embodiment of the present disclosure is not applied, the temperature of the semiconductor chip during the operation of the power module 10 may be expressed by the following equation:

$${T}_{ch} = {R}_{th} {P}_{ch} + {T}_{cw}$$

Here, T_{ch} represents the temperature of the semiconductor chip, Rₜₕ represents the thermal resistance of the power module 10, P_{ch} represents the power consumption of the semiconductor chip, and T_{cw} represents the temperature of the coolant 201. That is, when the power module 10 is operating, the temperature of the semiconductor chip increases as the thermal resistance of the power module 10 and the power consumption of the semiconductor chip increase, and the temperature of the semiconductor chip decreases as the temperature of the coolant 201 decreases.

On the other hand, when the first cooling unit 310 according to an exemplary embodiment of the present disclosure is applied, the temperature of the semiconductor chip may be expressed by the following equation:

$${T}_{ch} = {R}_{th} {P}_{ch} + {T}_{fe}$$

Here, T_{fe} represents the evaporation temperature of the fluid 311, and the coolant 201 heated to a certain extent undergoes heat transfer due to the evaporation of the fluid 311, allowing the temperature of the coolant (i.e., T_{cw}) to be regulated by the evaporation temperature of the fluid (i.e., T_{fe}). That is, the upper limit of the coolant temperature may be considered to be the boiling point (or around the boiling point) of the fluid.

By comparing the cases where the first cooling unit 310 is applied and not applied under the same conditions, it may be observed that by maintaining the temperature of the coolant 201 within the boiling point range of the fluid 311, the temperature of the semiconductor chip may be reduced by T_{cw}−T_{fe}, allowing for the application of an additional power of (T_{cw}−T_{fe})/Rₜₕ to the semiconductor chip.

Meanwhile, as shown in FIG. 2, the fluid tank 312 includes a shape of surrounding the external side of the second section 220 and may be penetrated by the second section 220 to allow contact between the fluid 311 and the second section 220. When the fluid tank 312 is configured in the present way, the fluid 311 and the second section 220 may directly contact with each other, promoting more efficient heat exchange therebetween, enhancing the cooling efficiency of the coolant 201.

However, contrary to what is illustrated in FIG. 2, the fluid tank 312 may also be attached to merely one side of the second section 220 without direct contact between the fluid 311 and the second section 220, allowing heat exchange between the fluid 311 and the coolant 201 to occur through the fluid tank 312.

Hereinafter, descriptions include the second cooling unit 320 and the control unit 330 according to an exemplary embodiment of the present disclosure with reference to FIG. 3.

FIG. 3 is a diagram illustrating a second cooling unit of a coolant cooler according to an exemplary embodiment of the present disclosure.

With reference to FIG. 3, the second cooling unit 320 according to an exemplary embodiment of the present disclosure may be connected to the second section 220 and operated by receiving energy from a power source, while the control unit 330 may be configured for controlling the second cooling unit 320 to cool the coolant 201 according to predetermined conditions.

During the operation, the second cooling unit 320 may transfer heat from the inside of the flow path 200 to the outside of the flow path 200, and for the present purpose, include at least one of a fan and a Peltier device, while the control unit 330 may be placed in various locations depending on the volume and connection method.

The power source supplying energy for the operation of the second cooling unit 320 may include, for example, a motor or a battery, and it may be placed in various locations depending on the volume and connection method.

Unlike the first cooling unit 310, the second cooling unit 320 operates under the control of the control unit 330, and when a predetermined operation condition is satisfied, the control unit 330 may be configured for controlling the operation of the second cooling unit 320. That is, when the second cooling unit 320 is applied, a more powerful cooling may be achieved compared to the first cooling unit 310, which maintains the temperature of the coolant 201 within a certain range.

For example, the predetermined condition may be satisfied when a power equal to or greater than a predetermined reference power is applied to the power module 10, and in the instant case, the control unit 330 may be configured for controlling the operation of the second cooling unit 320. The predetermined reference power may be set corresponding to the thermal resistance of the power module 10.

For the present purpose, the control unit 330 may be connected to a controller (such as a motor controller or a vehicle controller) connected to the power module 10 to obtain information related to the power applied to the semiconductor chip.

On the other hand, the predetermined condition may also be set to be satisfied when the temperature of the coolant 201 flowing into the first section 210 is equal to or greater than a predetermined reference temperature.

For the present purpose, the control unit 330 may obtain information related to the temperature of the coolant 201 from a sensor configured for measuring the temperature of the coolant 201, and the sensor may be placed in the vicinity of the first section 210.

When the second cooling unit 320 according to an exemplary embodiment of the present disclosure operates, the temperature of the semiconductor chip may be expressed by the following equation:

$${T}_{c h} = {R}_{t h} {P}_{c h} + {T}_{c w} - Δ T$$

Here, T_{cw} represents the temperature of the coolant 201 when the second cooling unit 320 is not operating, and ΔT represents the temperature decrease caused by operation of the second cooling unit 320. That is, compared to the case where the second cooling unit 320 is not operating, the temperature of the semiconductor chip decreases by ΔT, and accordingly, an additional power of A T/Rₜₕ may be applied to the semiconductor chip.

The thermal resistance of the power module 10 may vary depending on the temperature, i.e., have a smaller value as the temperature decreases, and may be designed, according to an exemplary embodiment of the present disclosure, to be initially greater than the thermal resistance required for the maximum output of the semiconductor chip, and when maximum output is needed, lowered through forced cooling. In the instant case, it is possible to increase the upper limit of the maximum output of the semiconductor chip within a range where the semiconductor chip is operable stably.

This allows for a reduction in manufacturing costs by enabling the design of the power module 10 with relaxed thermal resistance conditions, and ensures the reliability of the semiconductor chip output by controlling the temperature of the coolant 201.

Hereinafter, a description includes the case where the coolant cooler 300 includes both the first cooling unit 310 and the second cooling unit 320, with reference to FIG. 4.

FIG. 4 is a diagram illustrating a coolant cooler with both a first cooling unit and a second cooling unit together according to an exemplary embodiment of the present disclosure.

With reference to FIG. 4, the coolant cooler 300 may include a first cooling unit 310 including a fluid tank 312 containing a fluid 311 with a lower boiling point than that of the coolant 201 and connected to the external side of the second section 220, and a second cooling unit 320 connected to the second section 220 and operated by receiving energy from a power source, and a control unit 330 controlling the second cooling unit 320 to cool the coolant 201 according to predetermined conditions.

In the instant case, the predetermined conditions for cooling in the second section 220 may include a first condition for cooling the coolant 201 in the first cooling unit 310 and a second condition for cooling the coolant 201 in the second cooling unit 320.

For example, the first condition may be satisfied when the temperature of the coolant 201 is equal to or greater than the boiling point of the fluid 311 as described above, and the second condition may be satisfied when a power equal to or greater than a predetermined reference power is applied to the semiconductor chip of the power module 10 or when the temperature of the coolant 201 flowing into the first section 210 is equal to or greater than a predetermined reference temperature.

In the case where the coolant cooler 300 is configured as described above, the temperature management device of the power module may manage the temperature in two different modes.

That is, the coolant may be passively cooled by heat exchange with the fluid 311 in the first cooling unit 310 or actively cooled through a fan or Peltier device in the second cooling unit 320.

When the coolant is cooled by the second cooling unit 320, the temperature of the coolant 201 may be adjusted lower compared to when the coolant is cooled by the first cooling unit 310, and if necessary, in a stepwise manner.

Meanwhile, as shown in FIG. 4, the second cooling unit 320 may be connected to the external side of the first cooling unit 310.

Hereinafter, descriptions include the exemplary implementations of the flow path 200 according to an exemplary embodiment of the present disclosure with reference to FIG. 5 and FIG. 6.

FIG. 5 is a diagram illustrating a configuration where a second section of a flow path is formed in a parallel manner according to an exemplary embodiment of the present disclosure, and FIG. 6 is a diagram illustrating the configuration where a heat exchanger is applied to a second section of a flow path according to an exemplary embodiment of the present disclosure.

With reference to FIG. 5, the flow path 200 according to an exemplary embodiment of the present disclosure may include a plurality of channels connected in parallel and spaced from each other in the second section in a direction perpendicular to a direction of coolant flow 220 to increase the efficiency of coolant cooling.

With reference to FIG. 6, the flow path 200 according to an exemplary embodiment of the present disclosure may be provided with a heat exchanger 221 formed at least one of the internal and external portions of the second section 220 to transfer heat from the coolant 201.

The heat exchanger 221 may be implemented as a fin structure or a pin-fin structure.

Through the present configuration, it becomes possible to transfer heat from the coolant 201 to the coolant cooler 300, improving colling performance of the coolant 201.

Through the various embodiments of the present disclosure as described above, it becomes possible to reliably manage the temperature of the semiconductor chips in the power module, effectively ensuring the operational performance and reliability of the power module.

Furthermore, by enhancing the performance of the power module through temperature adjustment of the coolant, without requiring any modifications to the structure or materials of the power module, it becomes possible to allow for an expanded design flexibility and cost savings for the power module.

Furthermore, the term related to a control device such as “controller”, “control apparatus”, “control unit”, “control device”, “control module”, or “server”, etc refers to a hardware device including a memory and a processor configured to execute one or more steps interpreted as an algorithm structure. The memory stores algorithm steps, and the processor executes the algorithm steps to perform one or more processes of a method in accordance with various exemplary embodiments of the present disclosure. The control device according to exemplary embodiments of the present disclosure may be implemented through a nonvolatile memory configured to store algorithms for controlling operation of various components of a vehicle or data about software commands for executing the algorithms, and a processor configured to perform operation to be described above using the data stored in the memory. The memory and the processor may be individual chips. Alternatively, the memory and the processor may be integrated in a single chip. The processor may be implemented as one or more processors. The processor may include various logic circuits and operation circuits, may be configured to process data according to a program provided from the memory, and may be configured to generate a control signal according to the processing result.

The control device may be at least one microprocessor operated by a predetermined program which may include a series of commands for carrying out the method included in the aforementioned various exemplary embodiments of the present disclosure.

The aforementioned invention can also be embodied as computer readable codes on a computer readable recording medium. The computer readable recording medium is any data storage device that can store data which may be thereafter read by a computer system and store and execute program instructions which may be thereafter read by a computer system. Examples of the computer readable recording medium include Hard Disk Drive (HDD), solid state disk (SSD), silicon disk drive (SDD), read-only memory (ROM), random-access memory (RAM), CD-ROMs, magnetic tapes, floppy discs, optical data storage devices, etc and implementation as carrier waves (e.g., transmission over the Internet). Examples of the program instruction include machine language code such as those generated by a compiler, as well as high-level language code which may be executed by a computer using an interpreter or the like.

In various exemplary embodiments of the present disclosure, each operation described above may be performed by a control device, and the control device may be configured by a plurality of control devices, or an integrated single control device.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Furthermore, the terms such as “unit”, “module”, etc. included in the specification mean units for processing at least one function or operation, which may be implemented by hardware, software, or a combination thereof.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In the present specification, unless stated otherwise, a singular expression includes a plural expression unless the context clearly indicates otherwise.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. An apparatus for managing temperature of a power module, the apparatus comprising:
a flow path including a first section thermally connected to the power module and a second section connected in series to the first section for a coolant to flow from the second section to the first section through the first section and the second section; and
a coolant cooler thermally connected to the second section of the flow path and cooling the coolant flowing into the second section according to a predetermined condition.

2. The apparatus of claim 1, wherein the second section is positioned in an opposite direction to a direction facing the first section for the coolant cooled through heat exchange with an outside of the first section after passing through the first section to flow into the second section.

3. The apparatus of claim 1, wherein the coolant cooler includes a first cooling unit including a fluid tank filled with a fluid having a boiling point lower than a boiling point of the coolant and connected to an external side of the second section.

4. The apparatus of claim 3, wherein the predetermined condition is satisfied based on a temperature of the coolant flowing into the second section being equal to or greater than the boiling point of the fluid.

5. The apparatus of claim 3, wherein the fluid tank surrounds the external side of the second section and is penetrated by the second section for the fluid to contact with the external side of the second section.

6. The apparatus of claim 1, wherein the coolant cooler includes:
a second cooling unit connected to the second section and operated by receiving energy from a power source; and
a control unit electrically connected to the second cooling unit and configured for controlling the second cooling unit to cool the coolant according to the predetermined condition.

7. The apparatus of claim 6, wherein the second cooling unit includes at least one of a fan and a Peltier device.

8. The apparatus of claim 6, wherein the predetermined condition is satisfied based on a power equal to or greater than a predetermined reference power being applied to the power module.

9. The apparatus of claim 8, wherein the predetermined reference power is set corresponding to a thermal resistance of the power module.

10. The apparatus of claim 6, wherein the predetermined condition is satisfied based on a temperature of the coolant flowing into the first section being equal to or greater than a predetermined reference temperature.

11. The apparatus of claim 1, wherein the coolant cooler includes:
a first cooling unit including a fluid tank filled with a fluid having a boiling point lower than a boiling point of the coolant and connected to an external side of the second section:
a second cooling unit connected to the second section and operated by receiving energy from a power source; and
a control unit electrically connected to the second cooling unit and configured for controlling the second cooling unit to cool the coolant according to the predetermined condition.

12. The apparatus of claim 11, wherein the predetermined condition includes a first condition and a second condition, the first cooling unit cools the coolant flowing into the second section based on the first condition being satisfied, and the second cooling unit cools the coolant flowing into the second section based on the second condition being satisfied.

13. The apparatus of claim 12, wherein the first condition is satisfied based on a temperature of the coolant flowing into the second section being equal to or greater than the boiling point of the fluid.

14. The apparatus of claim 12, wherein the second condition is satisfied based on a power equal to or greater than a predetermined reference power being applied to the power module.

15. The apparatus of claim 14, wherein the predetermined reference power is set corresponding to a thermal resistance of the power module.

16. The apparatus of claim 12, wherein the second condition is satisfied based on a temperature of the coolant flowing into the first section being equal to or greater than a predetermined reference temperature.

17. The apparatus of claim 11, wherein the second cooling unit is connected to an external side of the first cooling unit.

18. The apparatus of claim 1, wherein the flow path includes a plurality of channels connected in parallel and spaced from each other in the second section in a direction perpendicular to a flow direction of the coolant.

19. The apparatus of claim 1, wherein the flow path includes a heat exchanger formed on at least one of internal and external portions of the second section to transfer heat of the coolant to the heat exchanger.
